(19) United States
(12) Patent Application Publication
(10) Pub. No.: US 2019/0356110 A1
(43) Pub. Date: Nov. 21, 2019

(54) ACTIVE OPTICAL CAVITY LASER HEATING MEDIUM

(71) Applicant: Intrepid Brands, LLC, Louisville, KY (US)

(72) Inventor: Rakesh Guduru, Weston, FL (US)

(21) Appl. No.: 16/414,085

(22) Filed: May 16, 2019

Related U.S. Application Data
(60) Provisional application No. 62/672,214, filed on May 16, 2018.

(51) Int. Cl. H01S 5/06; H01S 5/068; A24F 47/00; H01S 5/026

(52) U.S. Cl. CPC H01S 5/0612; H01S 5/06804; H01S 5/0267; H01S 5/0261; A24F 47/008

(57) ABSTRACT

An active optical cavity laser heating medium includes an active optical cavity heating element in contact with a vaporizable substance. A light beam may be emitted into the active optical cavity heating element from a light source. The active optical cavity may then act as a gain-medium, by enhancing the laser radiation, and as a transducer, by converting the optical radiation into heat. This heat generated by the active optical cavity may then heat the vaporizable substance in an electronic vaporization device. The active optical cavity laser heating medium may also determine the temperature of the active optical cavity.

### PRIORITY

This application claims priority to U.S. Provisional Patent Application No. 62/672,214, entitled “Active Optical Cavity Laser Heating Medium,” filed on May 16, 2018, the disclosure of which is hereby incorporated by reference herein.

### TECHNICAL FIELD

The disclosure is directed to an active optical cavity based laser heating medium. The active optical cavity based laser heating medium may be used as part of an electronic vaporization device, such as an e-cigarette or personal vaporizer, to vaporize certain materials.

### BACKGROUND

An electronic vaporization device may simulate the feeling of smoking by heating a substance to generate an aerosol, commonly called a “vapor”, that a user inhales. Vaporization provides an alternative to combustion for the delivery and consumption of various substances including, but not limited to liquids, i.e., “E-liquids,” waxes, gels and combinations thereof (singularly, “a vaporizable substance,” collectively, “vaporizable substances”). Non-limiting examples of components of vaporizable substances include: glycerin, propylene glycol, flavorings, nicotine, medicaments and combinations thereof. Vaporization may be accomplished using electronic vaporization devices, including, but not limited to, electronic cigarettes, electronic cigars, electronic pipes and electronic vaporizers (singularly “EVD,” collectively, “EVDs”).

While EVDs may reduce the exposure to toxins as compared to traditional smoking, there may be a cause for concern relating to consumer exposure to trace metal(s) through vapor inhalation. EVDs typically use resistive heating to vaporize the liquids in an atomizer by passing a high current through a conductor, such as a metallic coil (i.e., nickel, aluminum, silver, chromium, iron, Kanthal, Nichrome, etc.) to produce heat, thereby generating the vapor for inhalation. Such heat and harsh environments in the atomizer may cause the metallic coil to oxidize, degrade, volatize, and/or corrode, contaminating the vapor with trace metal(s). Thus, in some instances, it may be desirable to minimize the process of oxidation, degradation, volatilization, and/or corrosion of the metallic coil of the atomizer.

The resistive heating medium of a typical EVD may further have a high energy consumption because a high current is needed to reach a high temperature in the atomizer. Such a high energy consumption may require a long warm-up time for the atomizer to reach operating temperature and may also require the battery of the EVD to be charged and/or replaced often. Accordingly, in some instances, it may be desirable to provide a heating element for an EVD that is more energy efficient to shorten the amount of time for the EVD to reach operating temperature and/or to lengthen the life of the battery.

While a variety of heating mediums have been made and used, it is believed that no one prior to the inventor has made or used an invention as described herein.

### SUMMARY

The unique solution that addresses the aforementioned problems is an active optical cavity laser heating medium with an atomizer comprising an active optical cavity heating element in contact with a vaporizable substance. The atomizer of the active optical cavity laser heating medium may be actuated by a control unit comprising a light source, such as a laser diode. The light source may be condensed into a light beam using a focusing lens and emitted into the active optical cavity. The active optical cavity may then act as a gain-medium, by enhancing the laser radiation, and as a transducer, by converting the optical radiation into heat. This heat generated by the active optical cavity may then heat the vaporizable substance in the EVD. The active optical cavity laser heating medium may also determine the temperature of the active optical cavity. Such an active optical cavity laser heating medium may improve the safety of the EVD by reducing or eliminating the oxidation, degradation, volatization, and/or corrosion of the atomizer, as well as reduce the energy consumption of the EVD.

### BRIEF DESCRIPTION OF THE DRAWINGS

While the specification concludes with claims which particularly point out and distinctly claim the invention, it is believed the present invention will be better understood from the following description of certain examples taken in conjunction with the accompanying drawings, in which like reference numerals identify the same elements and in which:

FIG. 1 depicts a cross-sectional view of a typical Electronic Vaporization Device.

FIG. 2 depicts a cross-sectional view of a chamber of the EVD of FIG. 1.

FIG. 3 depicts a schematic of an optical cavity laser heating medium, which may be used in a typical EVD as shown in FIG. 1, having an active optical cavity in a coiled position about a wicking material.

FIG. 4 depicts a schematic of the active optical cavity of FIG. 3 in an uncoiled position in direct contact with a vaporizable substance.

FIG. 5 depicts a schematic of an uncoiled active optical cavity of the heating medium of FIG. 3.

FIG. 5A depicts an enlarged schematic of the uncoiled active optical cavity of FIG. 5.

FIG. 6 depicts an enlarged schematic of another uncoiled active optical cavity for use with the optical cavity laser heating medium of FIG. 3.

FIG. 7 depicts a schematic of an atomizer of the heating medium of FIG. 3.

FIG. 8 depicts a schematic of another optical cavity laser heating medium, which may be used in a typical EVD as shown in FIG. 1.

The drawings are not intended to be limiting in any way, and it is contemplated that various embodiments of the invention may be carried out in a variety of other ways, including those not necessarily depicted in the drawings. The accompanying drawings incorporated in and forming a part of the specification illustrate several aspects of the present invention, and together with the description serve to explain the principles of the invention; it being understood, however, that this invention is not limited to the precise arrangements shown.

### DETAILED DESCRIPTION

The following description of certain examples of the invention should not be used to limit the scope of the present invention. Other examples, features, aspects, embodiments, and advantages of the invention will become apparent to those skilled in the art from the following description, which is by way of illustration, one of the best modes contemplated for carrying out the invention. As will be realized, the invention is capable of other different and obvious aspects, all without departing from the invention. Accordingly, the drawings and descriptions should be regarded as illustrative in nature and not restrictive.

All percentages, parts and ratios as used herein, are by weight of the total composition of ambient moisture-activatable surface treatment powder, unless otherwise specified. All such weights, as they pertain to listed ingredients, are based on the active level and, therefore, do not include solvents or by-products that may be included in commercially available materials, unless otherwise specified.

Numerical ranges as used herein are intended to include every number and subset of numbers within that range, whether specifically disclosed or not. Further, these numerical ranges should be construed as providing support for a claim directed to any number or subset of numbers in that range. For example, a disclosure of from 1 to 10 should be construed as supporting a range of from 2 to 8, from 3 to 7, from 5 to 6, from 1 to 9, from 3.6 to 4.6, from 3.5 to 9.9 and so forth.

All references to singular characteristics or limitations of the present disclosure shall include the corresponding plural characteristic or limitation and vice versa, unless otherwise specified or clearly implied to the contrary by the context in which the reference is made.

All combinations of method or process steps as used herein can be performed in any order, unless otherwise specified or clearly implied to the contrary by the context in which the referenced combination is made.

As used herein, the term “comprising” means that the various components, ingredients, or steps, can be conjointly employed in practicing the present invention. Accordingly, the term “comprising” encompasses the more restrictive terms “consisting essentially of” and “consisting of.”

As used herein, “trace metal” collectively refers to metal, metal alloy or combinations of metal and metal alloy that is present in a vapor in a small, but measurable amount.

As used herein, “substantially free” refers to an amount in a vapor of about 1 wt. % or less, about 0.1 wt. % or less, about 0.01 wt. % or less or 0% (i.e., completely free of), one or more trace metals.

As used herein, “chamber,” “liquid chamber,” “tank,” “liquidmizer,” “cartomizer,” “disposable pod” and “clearomizer,” are used interchangeably to mean a reservoir that contains vaporizable substance to be vaporized by an EVD.

It will be appreciated that any one or more of the teachings, expressions, versions, examples, etc. described herein may be combined with any one or more of the other teachings, expressions, versions, examples, etc. that are described herein. The following-described teachings, expressions, versions, examples, etc. should therefore not be viewed in isolation relative to each other. Various suitable ways in which the teachings herein may be combined will be readily apparent to those of ordinary skill in the art in view of the teachings herein. Such modifications and variations are intended to be included within the scope of the claims.

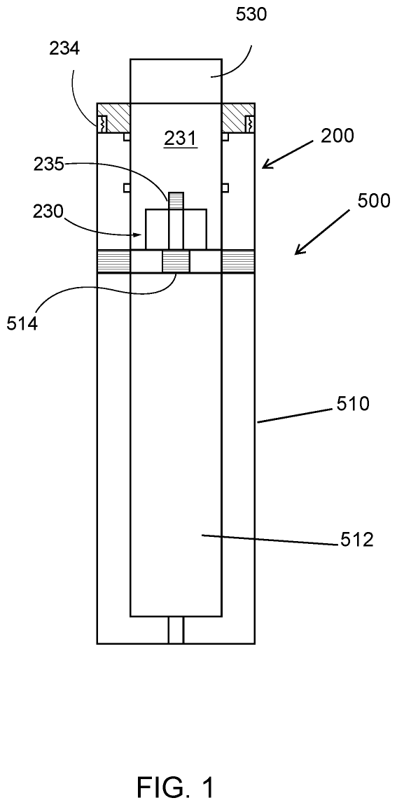

FIG. 1 shows a typical EVD 500 comprising a battery compartment 510 containing a battery 512 that is removably attached to a chamber 200 by connector 514. The chamber may be filled with a vaporizable substance through its open top, i.e., be a “top-filled chamber,” or it may be filled with a vaporizable substance through its open bottom, i.e., a “bottom-filled chamber.” As is known in the art, some EVDs comprise a battery compartment that is permanently affixed to a chamber of an EVD.

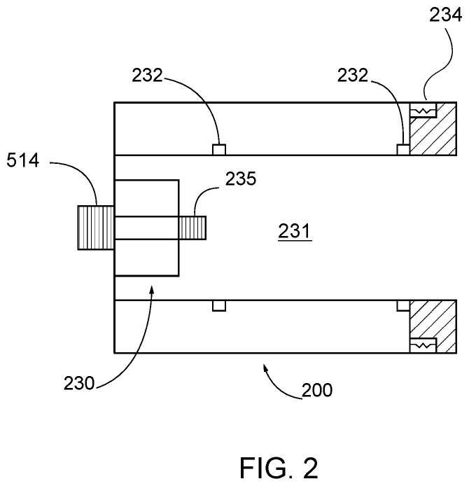

FIG. 2 shows the chamber 200 of FIG. 1 comprising an atomizer assembly 230. As illustrated, the atomizer assembly 230 comprises a metallic coil 235. This metallic coil 235 can be wrapped within an absorbent wick material such that the metallic coil 235 is positioned within the absorbent wick material. In some other versions, the absorbent wick material can be inserted through the metallic coil 235 such that the metallic coil 235 is positioned about the absorbent wick material. Exemplary wick material of use may be selected from cotton, nylon, porous ceramic and combinations thereof.

Extending from the atomizer assembly 230 is a vapor chimney 231, which is surrounded in part by a silicone or rubber ring 232. When the chamber 200 is assembled, the atomizer assembly 230 and vapor chimney 231 fit into the chamber 200. The chamber 200 is capped at its open top by a hollow metal ring 234 that is threaded on the inside and which serves as the attachment point of the mouthpiece to the chamber 200.

Accordingly, the metallic coil 235 of the atomizer assembly 230 becomes hot when supplied with electricity from the battery compartment 510 due to its resistance to the flow of electric current. The wick material in turn acts to transport the vaporizable substance, i.e., the E-liquid, gel or melted wax, to the metallic coil 235 to heat it and release vapor. The resulting vapor may then pass through the vapor chimney 231 to be delivered to the consumer via the mouthpiece 530.

Because heat and harsh environments in the atomizer assembly 230 may cause the metallic coil 235 to oxidize, degrade, volatilize, and/or corrode, the resulting vapor may be contaminated with one or more trace metals. Further, the resistive heating medium of the atomizer assembly 230 may further have a high energy consumption because a high current is needed to reach a high temperature in the atomizer. Accordingly, an active optical cavity laser heating medium may be provided to heat the vaporizable substance of an EVD instead of via a typical resistive heating method. For instance, an optical source, such as a laser, may heat an active optical cavity (AOC) coated with a light transducing material to produce heat. This may be used in an EVD to minimize contaminated vapor because the optical cavity laser heating medium prevents metal from being in direct contact with the vaporizable substance and/or the wicking material. The AOC may also be more energy efficient to shorten the amount of time for the EVD to reach operating temperature and/or to lengthen the life of the battery.

For instance, such a heating medium may use less power as compared to a typical resistive heating method. For instance, typical resistive heating methods may have a high energy consumption because a high current is needed to reach a high temperature in the atomizer. For instance, the atomizer may routinely reach temperatures of from about 150° C. to about 600° C., from about 180° C. to about 300° C. or from about 150° C. to about 180° C. Further, the atomizer assembly may routinely reach a temperature of about 180° C. or about 200° C. Such a high energy consumption may require the battery of the EVD to be charged and/or replaced often. Moreover, using optical sources, such as lasers, to vaporize liquid directly without a gain medium may need a high-power laser, a wide beam spot, and/or thermally insulated wicks. Such components may come with a health risk or high energy requirements. Accordingly, enclosing the optical source in an AOC gain medium and coiling it around the wick material may provide more surface area to heat the vaporizable substance, thereby reducing the energy required to operate an EVD. An AOC laser heating medium may thereby improve the safety and efficiency of an EVD.

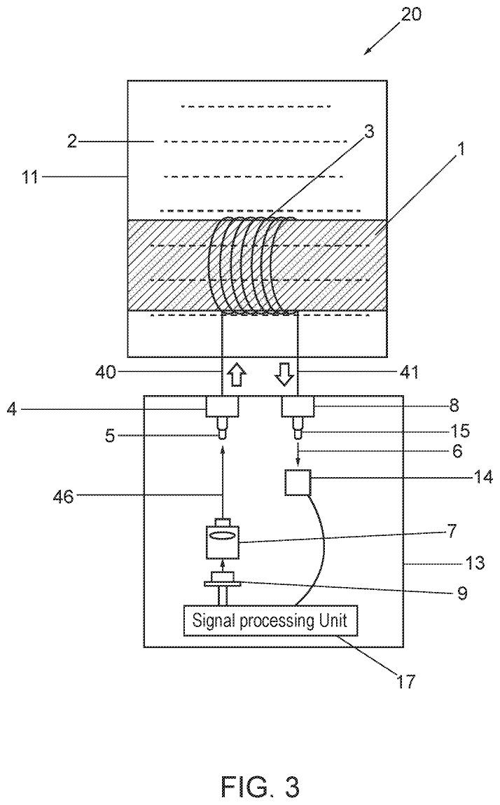

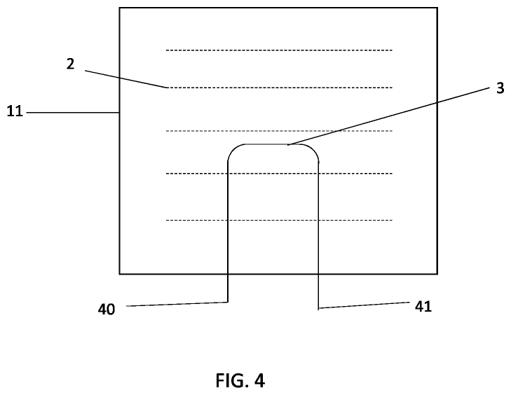

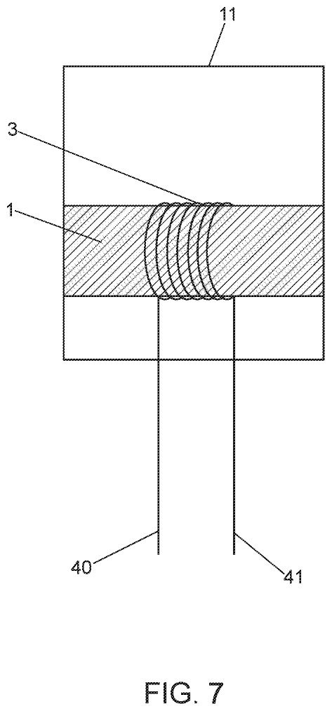

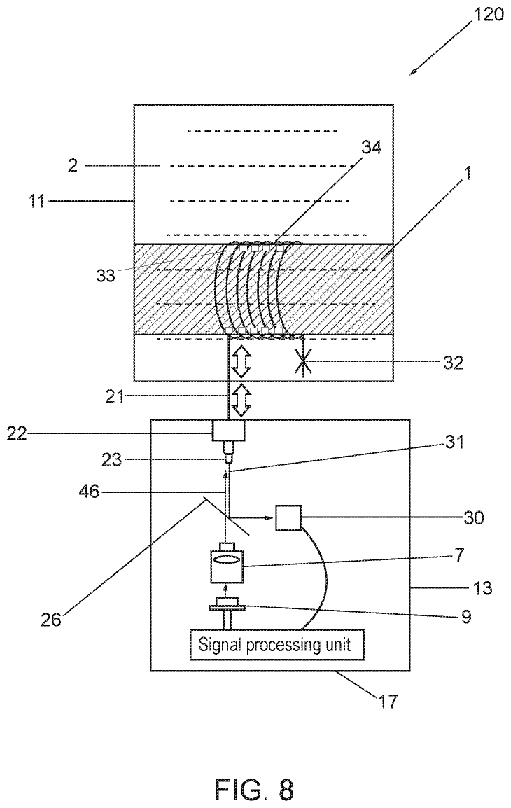

Referring to FIG. 3, an AOC laser heating medium 20 for an EVD is shown comprising a control unit 13 and an atomizer 11. The control unit 13 comprises a laser source 9, a focusing lens 7, a photodetector 14, a first fiber connector 4, a second fiber connector 8, and a signal processing unit 17. The atomizer 11 comprises an AOC 3 coiled around wicking material 1 (FIG. 7), such that an exterior surface of the AOC 3 contacts the wicking material 1, to vaporize the vaporizable substance 2. In some other versions, the AOC 3 of the atomizer 11 is in direct contact with the vaporizable substance 2, without the need for a wicking material, as shown in FIG. 4. The light source 9 of the control unit 13 may comprise a laser diode having a minimum power of about 1 milliwatts to about 10 watts, such as about 2 watts to about 4 watts. The light source 9 may be actuated by the signal processing unit 17. The focusing lens 7 is positioned downstream of the light source 9 and may condense a light beam 46 emitted from the light source 9 into the AOC 3 of the atomizer 11 at point 5 through the first fiber connector 4, such as a fiber-optic connector/physical contact (FC/PC) connection port or other light alignment optics. For instance, a first end 40 of the AOC 3 may be inserted into the FC/PC ferrule to connect the atomizer 11 to the control unit 13 with no requirement of beam alignment. Locating the FC/PC connection port in the control unit 13, along with the pre-calculated focusing optics, may ensure a maximum light coupling efficacy. This configuration may thereby eliminate beam alignment problems associated when an atomizer 11 is replaced and/or reconnected.

The AOC 3 may then act as a gain-medium, by enhancing the laser radiation, and as a transducer, by converting the optical radiation into heat, such as to temperatures of about 150° C. to about 300° C., from about 180° C. to about 200° C. or from about 150° C. to about 180° C. Further, the atomizer assembly may routinely reach a temperature of about 180° C. or about 200° C. The transmitted light beam 6 from the second end 41 of the AOC 3 may be sent back into the control unit 13 through the second fiber connector 8, such as an FC/PC connection port described above. The change in the optical signal of the transmitted light beam 6 may then be monitored by the photodetector 14. The photodetector 14 is coupled with the signal processing unit 17. The signal processing unit 17 may then calculate the temperature of the AOC 3 using sensing parameters and signals received from the photodetector 14. The signal processing unit 17 may then adjust the temperature of the AOC 3 based on the measured temperature of the photodetector 14.

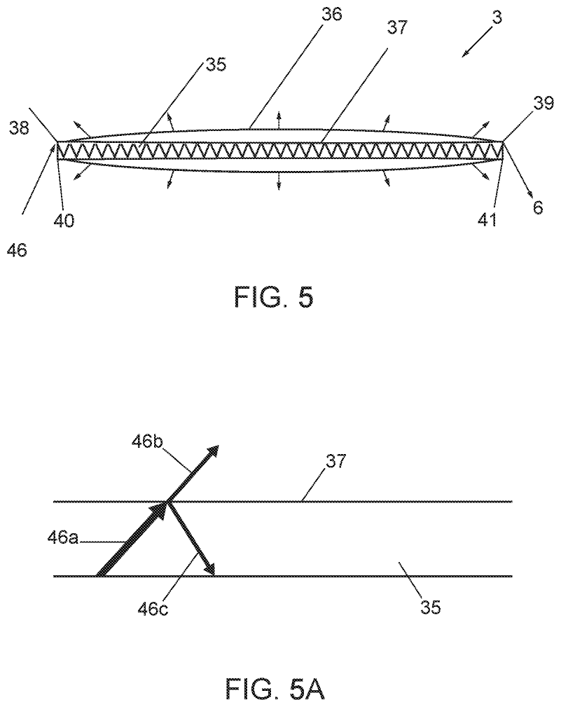

An uncoiled AOC 3 is shown in FIG. 5 comprising a conduit 37 forming a cavity 35 within the conduit 37. The conduit 37 may be made of a high temperature resistive material, such as silica glass tubing and/or fiber optic polymers, and may further be either flexible or rigid. In some versions, the conduit 37 is formed by a flexible fused silica glass tubing to allow the AOC 3 to be more easily wrapped around the wicking material 1 (FIG. 3). In some other versions, the conduit 37 is not wrapped about a wicking material and may maintain a substantially tubular shape (FIG. 3A). The conduit 37 of the AOC 3 may have a length of about 5 cm, an inner diameter of about 1000 micrometers, and an outer diameter of about 1200 micrometers. Still other suitable dimensions and configurations for the conduit 37 will be apparent to one with ordinary skill in the art in view of the teachings herein. Accordingly, the light beam 46 emitted from the light source 9 may enter the AOC 3 at a first opening 38 of the first end 40 of the conduit 37 at an angle, such as about 30°, and get reflected many times along the cavity 35 until the transmitted light beam 6 exits the AOC 3 at a second opening 39 of the second end 41 of the conduit 37.

As best seen in FIG. 5A, the light beam 46a is transmitted within the cavity 35 of the AOC 3 and contacts the wall the conduit 37 of the AOC 3 such that a first portion 46b of the light energy is absorbed by the conduit 37 to produce radiant heat 36 (see FIG. 4) and a second portion 46c of the light energy is reflected by the conduit 37 to continue transmitting the light beam 46 through the cavity 35. The interior surface of the conduit 37 is thereby light absorbing over the first portion 46b of the wavelengths of the light beam 46 to generate radiant heat, while also being highly reflective over the second portion 46c of the wavelengths of the light beam 46 to act as an optical gain medium by amplifying the light beam 46 for those wavelengths. This absorption and reflection of the light beam 46 continues to occur through the length of the conduit 37 each time the light beam 46 is directed to the wall of the conduit 37 to reflect the light beam 46 and to produce radiant heat 36 through the length of the AOC 3.

In some versions, the AOC 3 may further amplify the reflected portion 46c of the light beam 46 using one or more of the following properties: light reflective coatings, optical resonators, Febry-Perot geometry, nanoparticles, rare-earth dopants, dyes, gases, etc. For instance, the interior surface of the conduit 37 of the AOC 3 may be coated with a highly-reflective material, such as precious metals, to produce a highly-reflective surface in a Fabry-Perot resonator type geometry to create a long-standing wave. Exemplary highly reflective precious metals may be selected from the group of silver, gold, and combinations thereof. This kind of structure may amplify the emitted beam 46 through optical resonance. Such a gain in light energy may produce heat locally, such as temperatures up to about 600° C. using the surface plasmon resonance phenomenon. Additionally or alternatively, the temperature in the AOC 3 may be increased by doping the cavity 35 with a photosensitive metal. Exemplary photosensitive metals of use may be selected from rare earth metals, such as Co, Nd, Er, Yb, etc. Additionally or alternatively, the cavity 35 may be coated in nanoparticles of different sizes to absorb specific wavelengths of light to generate heat. For instance, varying the sizes of silver nanoparticles applied to the cavity 35 to range from about 10 nanometers (nm) to about 100 nm may result in absorbance of light having wavelengths from about 350 nm to about 600 nm in order to produce radiant heat. The cavity 35 may also be filled and/or coated with any other light transducing materials, including graphene, to produce heat. Such light transducing material may have a light absorption coefficient from about 1 to about 200 decibels per centimeter.

Restricting the coating and/or dopants to the inner surface of the conduit 37 may minimize and/or eliminate the exposure of vapor contaminate because no metal is in direct contact with the vaporizable substance 2 and/or wicking material 1, which contact the outer surface of the conduit 37. Accordingly, when a wicking material is used, the wicking material 1 draws in the vaporizable substance 2 using capillary forces and vaporization achieved by heating the vaporizable substance 2 to its boiling point using the AOC laser heating medium 20. When a wicking material is not used, the AOC laser heating medium 20 may directly heat the vaporizable substance 2. The energy required to heat the wicking material 1 and/or vaporizable substance by the AOC laser heating medium 20 may also be reduced, such as to less than about 1 watt. Further, the atomizer 11 containing the AOC 3 may be inexpensively replaced if the other components of the AOC laser heating medium 20 are housed separately in the control unit 13, within the body of the EVD. Still other suitable configurations for the AOC laser heating medium 20 will be apparent to one with ordinary skill in the art in view of the teachings herein.

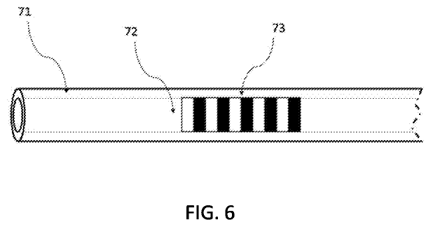

For instance, the same can also achieved by using a fiber optic as best seen in FIG. 6. Fiber optic typically includes two parts, an internal cavity, or core 72, that is surrounded by an outer cladding 71. The core 72 may transmit the light beam 9 along the length of the fiber optic, and the cladding may reflect the light beam 9 into the core 72 by creating a total internal reflection. In some versions, the fiber optic may comprise a Braggs Grating 73, which can pump at least a portion of the light beam 9 into the cladding 71. In some versions, the cladding material is doped with light transducing material that may convert light energy into heat energy, such that the produced heat can be used as a heating medium for an EVD.

After being absorbed by the AOC 3, the transmitted light beam 6 exits the AOC 3 and is sent to the control unit 13, as shown in FIG. 3, through the second fiber connector 8 at point 15, where it is captured by the photodetector 14. The signal processing unit 17 may then calculate the temperature of the cavity 35 using sensing parameters and the signals received from the photodetector 14. For instance, the radiance of the transmitted light beam 6 after being significantly absorbed by the AOC 3 may be measured with the photodetector 14 and the temperature may be calculated using Stefan-Boltzmann law, as provided in the formula below.

AOC temperature sensing parameters may be calculated using Stefan-Boltzmann law:

$$T = \sqrt[4]{\frac{L \text{?}}{ɛσ}}$$

$$\text{?} \text{indicates text missing or illegible when filed}$$

Where T is the temperature of the AOC in Kelvin,
L is the radiance (watts per square meter per steradian),
ε is the emissivity (<1), and
σ is the Stefan-Bolzmann constant (5.670373×10⁻⁸ watt per meter squared per kelvin to the fourth (W m⁻² K⁻⁴)).

The temperature of the AOC 3 may then be calculated by the signal processing unit 17 from a predetermined calibration plot. The calibration plot can be determined using parameters such as optical power, time, and/or heat generated. In this configuration, a partially reflective attenuator may be used to transmit out the unabsorbed laser radiation to the photodetector 14 to determine the temperature of the AOC 3. Still other suitable configurations for determining the temperature of the AOC 3 will be apparent to one with ordinary skill in the art.

For instance, in some other versions, the temperature of the AOC 3 may be measured by determining a shift in Bragg wavelength, instead of using light absorption as described above. Another exemplary AOC laser heating medium 120 is shown in FIG. 6 that is similar to the AOC laser heating medium 20 described above, except that the AOC laser heating medium 120 comprises an AOC 34 inscribed with Bragg grating 33 used to measure the temperature of the AOC 34. The interior surface of the AOC 34 may be inscribed with a segment of between about 2 mm and about 1 cm of Bragg gratings, which reflect a particular wavelength, or Bragg wavelength, of light depending on the temperature of the AOC 34. The temperature of the AOC 34 may thereby be monitored using a shift in the Bragg wavelength. The Bragg wavelength is given by the effective refractive index of the grating (ne) and the spatial refractive index of the perturbation period (∧) using the formula below.

Bragg Conditions: λB=2ne∧

AOC temperature sensing parameters:

$$\frac{Δλ B , T}{λ B} = \frac{1}{λ B} \frac{dλ B}{λ B} = ( \frac{1}{ne} \frac{\partial ne}{\partial T} - \frac{\partial {ne}^{2}}{\partial T} ( {p}_{11} + 2 {p}_{12} ) {α}_{T} + {α}_{T} ) .$$

Where

$$\frac{Δλ B , T}{λ B}$$

is the relative change in the Bragg wavelength per kelvin temperature change,

$$\frac{\partial ne}{\partial T}$$

is the thermos-optical coefficient,
p₁₁, p₁₂ are the Pockel's coefficient for photo-elastic effect, and
α_{I} is the thermal expansion coefficient of the cavity.

Referring back to FIG. 6, for a configuration with Bragg grating, only one fiber connector 22 is needed at the beam incident 23 where the light beam 46 from the light source 9 is emitted into the first end 21 of the AOC 34, while the other end of the AOC 34 is attenuated to reflect the light beam 46 back into the cavity 35 of the AOC 34 using a reflective attenuator 32. The reflective attenuator 32 may be at least one fully-reflective attenuator to maximize the beam amplification. In this configuration, light enters and leaves the cavity 35 from the same side 21 of the AOC 34. The reflected light 31 from the cavity 35 may then be passed through a beam splitter 26 to reach the photodetector 30. Accordingly, the temperature of the AOC 34 may be determined by detecting the reflected light signal 31 at the same point where the beam 46 is emitted into the AOC 34 via a beam splitter 26 and a photodetector 30. The signal processing unit 17 may then use the cavity sensing parameters, such as reflected energy and/or emitted beam energy, to calculate the temperature of the AOC 34 based on the signal output from the photodetector 30 and the Bragg conditions described above.

With respect to the configuration using light absorption to measure the temperature, the Bragg grating inscription may increase the cost of the AOC 34 because of the additional manufacturing steps to satisfy the Bragg conditions. Alternatively, the configuration with Bragg grating may increase the accuracy of the temperature measurement and it may be easier to mass produce by simplifying the device to only require one fiber connector 22 to attach the atomizer 11 to the control unit 13.

Thus, the AOC 3, 34 may produce heat to vaporize a vaporizable substance within an EVD while exhibiting a high resistance to oxidation, corrosion, volatilization, and/or degradation. The AOC 3, 34 is thereby operable to vaporize a vaporizable substance within an EVD to provide a vapor that is substantially free from one or more trace metals. Exemplary trace metals may be selected from nickel, aluminum, silver, chromium, iron, an alloy of FeCrAl (e.g., Kanthal® which is an alloy comprising 20-30 wt % Cr, 20-30 wt % Al and the balance Fe (Sandvik Group, Sweden), nichrome (an alloy of nickel with chromium (at 10-20 wt %) and sometimes iron (up to 25 wt %), platinum, stainless steel, titanium, and combinations thereof. The AOC 3, 34 may further be more energy efficient to shorten the amount of time for the EVD to reach operating temperature and/or to lengthen the life of the battery.

Having shown and described various versions of the present invention, further adaptations of the methods and systems described herein may be accomplished by appropriate modifications by one of ordinary skill in the art without departing from the scope of the present invention. Several of such potential modifications have been mentioned, and others will be apparent to those skilled in the art. For instance, the examples, versions, geometrics, materials, dimensions, ratios, steps, and the like discussed above are illustrative and are not required. Accordingly, the scope of the present invention should be considered in terms of the following claims and is understood not to be limited to the details of structure and operation shown and described in the specification and drawings.

The following examples relate to various non-exhaustive ways in which the teachings herein may be combined or applied. It should be understood that the following examples are not intended to restrict the coverage of any claims that may be presented at any time in this application or in subsequent filings of this application. No disclaimer is intended. The following examples are being provided for nothing more than merely illustrative purposes. It is contemplated that the various teachings herein may be arranged and applied in numerous other ways. It is also contemplated that some variations may omit certain features referred to in the below examples. Therefore, none of the aspects or features referred to below should be deemed critical unless otherwise explicitly indicated as such at a later date by the inventors or by a successor in interest to the inventors. If any claims are presented in this application or in subsequent filings related to this application that include additional features beyond those referred to below, those additional features shall not be presumed to have been added for any reason relating to patentability.

### EXAMPLE 1

A heating element for vaporizing a vaporizable substance in an electronic vaporization device comprising:
an atomizer comprising an active optical cavity coupled with the vaporizable substance; and
a control unit comprising:
   a laser source configured to emit a light beam,
   a focusing lens positioned downstream of the light source, wherein the focusing lens is configured to condense the light beam emitted from the light source and transmit the condensed light beam into the active optical cavity, wherein the active optical cavity comprises a light transducing material configured to absorb at least a portion the condensed light beam to thereby convert the optical radiation of the light beam into heat,
   a photodetector positioned downstream of the active optical cavity, wherein the photodetector is configured to measure an amount of light unabsorbed by the active optical cavity from the light beam transmitted from the active optical cavity, and
   a signal processing unit coupled with the photodetector, wherein the signal processing unit is configured to calculate a temperature of the active optical cavity based on the measurement from the photodetector.

### EXAMPLE 2

A heating element according to example 1 or any of the following examples up to example 19, wherein the light source comprises a laser diode.

### EXAMPLE 3

A heating element according to any one of the preceding examples or following examples up to example 19, wherein the light source is coupled with the signal processing unit such that the signal processing unit is configured to actuate the light source.

### EXAMPLE 4

A heating element according to any one of the preceding examples or following examples up to example 19, wherein the active optical cavity comprises a conduit forming an interior cavity.

### EXAMPLE 5

A heating element according to any one of the preceding examples or following examples up to example 19, wherein the active optical cavity comprises a high temperature resistive silica glass tubing.

### EXAMPLE 6

A heating element according to any one of the preceding examples or following examples up to example 19, wherein the active optical cavity is flexible to wrap around a wicking material.

### EXAMPLE 7

A heating element according to any one of the preceding examples or following examples up to example 19, wherein the active optical cavity is a gain-medium configured to amplify the light beam.

### EXAMPLE 8

A heating element according to any one of the preceding examples or following examples up to example 19, wherein an inner surface of the active optical cavity is coated in a highly-reflective material.

### EXAMPLE 9

A heating element according to any one of the preceding examples or following examples up to example 19, wherein an inner surface of the active optical cavity is doped with a photosensitive rare earth metal.

### EXAMPLE 10

A heating element according to any one of the preceding examples or following examples up to example 19, wherein an inner surface of the active optical cavity is coated in nanoparticles of different sizes to absorb specific wavelengths of the light beam.

### EXAMPLE 11

A heating element according to any one of the preceding examples or following examples up to example 19, wherein an inner surface of the active optical cavity is coated with a light transducing material.

### EXAMPLE 12

A heating element according to any one of the preceding examples or following examples up to example 19, wherein the active optical cavity has a light absorption coefficient between about 1 and about 200 dB/cm.

### EXAMPLE 13

A heating element according to any one of the preceding examples or following examples up to example 19, further comprising a fiber connector to couple the atomizer with the control unit such that the light beam is transmitted between the atomizer and the control unit through the fiber connector.

### EXAMPLE 14

A heating element according to any one of the preceding examples or following examples up to example 19, wherein the signal processing unit is configured to calculate the temperature of the active optical cavity based on a predetermined calibration plot.

### EXAMPLE 15

A heating element according to any one of the preceding examples or following examples up to example 19, further comprising a partially reflective attenuator configured to transmit the light beam from the active optical cavity to the photodetector.

### EXAMPLE 16

A heating element according to any one of the preceding examples or following examples up to example 19, wherein the signal processing unit is configured to calculate the temperature of the active optical cavity using Bragg grating inscribed on an interior surface of the active optical cavity.

### EXAMPLE 17

A heating element according to example 16, further comprising a fully-reflective attenuator configured to reflect the light beam from a second end of the active optical cavity back to a first end of the active optical cavity.

### EXAMPLE 18

A heating element according to example 16 or 17, further comprising a beam splitter configured to pass the reflected light beam from the active optical cavity to the photodetector.

### EXAMPLE 19

A heating element for vaporizing a vaporizable substance in an electronic vaporization device comprising:

an active optical cavity coupled with a vaporizable substance; and

a laser source configured to emit a light beam into the active optical cavity;
wherein the active optical cavity comprises a light transducing material configured to absorb a portion the light beam to thereby convert the optical radiation of the light beam into heat.

### EXAMPLE 20

A heating element according to example 19, further comprising a photodetector configured to measure the light beam transmitted from the active optical cavity and a signal processing unit coupled with the photodetector, wherein the signal processing unit is configured to calculate the temperature of the active optical cavity based on the measurement from the photodetector.

### EXAMPLE 21

A method of operating a heating element to heat a vaporizable substance, wherein the heating element comprises an active optical cavity, the method comprising the steps of:
emitting a light from a light source;
condensing the light emitted from the light source into a light beam;
transmitting the light beam into the active optical cavity; and
absorbing at least a portion of the light beam within the active optical cavity to generate heat.

### EXAMPLE 22

A method according to example 21 or any of the following examples, further comprising measuring the light beam exiting the active optical cavity with a photodetector.

### EXAMPLE 23

A method according to example 22 or any of the following examples, further comprising calculating the temperature of the active optical cavity based on the measurement of the photodetector.

### EXAMPLE 24

A method according to example 23, further comprising calculating the temperature based on the at least a portion of the light beam absorbed by the active optical cavity.

### EXAMPLE 25

A method according to example 23, further comprising calculating the temperature using Bragg grating inscribed on an interior surface of the active optical cavity.

### EXAMPLE 26

The method according to any of the examples 21 to 25, further comprising vaporizing a vaporizable substance from the heat generated by the active optical cavity to produce a vapor that is substantially free from trace metals.

### EXAMPLE 27

The method according to example 26, wherein the trace metals are selected from a group consisting of nickel, aluminum, silver, chromium, iron, Kanthal, Nichrome, platinum, and combinations thereof.

I/We claim:

1. A heating element for vaporizing a vaporizable substance in an electronic vaporization device comprising:
an atomizer comprising an active optical cavity coupled with the vaporizable substance; and
a control unit comprising:
a laser source configured to emit a light beam,
a focusing lens positioned downstream of the light source, wherein the focusing lens is configured to condense the light beam emitted from the light source and transmit the condensed light beam into the active optical cavity, wherein the active optical cavity comprises a light transducing material configured to absorb at least a portion the condensed light beam to thereby convert the optical radiation of the light beam into heat,
a photodetector positioned downstream of the active optical cavity, wherein the photodetector is configured to measure an amount of light unabsorbed by the active optical cavity from the light beam transmitted from the active optical cavity, and
a signal processing unit coupled with the photodetector, wherein the signal processing unit is configured to calculate a temperature of the active optical cavity based on the measurement from the photodetector.

2. The heating element of claim 1, wherein the light source comprises a laser diode.

3. The heating element of claim 1, wherein the light source is coupled with the signal processing unit such that the signal processing unit is configured to actuate the light source.

4. The heating element of claim 1, wherein the active optical cavity comprises a high temperature resistive silica glass tubing.

5. The heating element of claim 1, wherein the active optical cavity is flexible to wrap around a wicking material.

6. The heating element of claim 1, wherein an inner surface of the active optical cavity is coated in a highly-reflective material.

7. The heating element of claim 1, wherein an inner surface of the active optical cavity is doped with a photosensitive rare earth metal.

8. The heating element of claim 1, wherein an inner surface of the active optical cavity is coated in nanoparticles of different sizes to absorb specific wavelengths of the light beam.

9. The heating element of claim 1, wherein an inner surface of the active optical cavity is coated with a light transducing material.

10. The heating element of claim 1, further comprising a fiber connector to couple the atomizer with the control unit such that the light beam is transmitted between the atomizer and the control unit through the fiber connector.

11. The heating element of claim 1, wherein the signal processing unit is configured to calculate the temperature of the active optical cavity based on a predetermined calibration plot.

12. The heating element of claim 1, further comprising a partially reflective attenuator configured to transmit the light beam from the active optical cavity to the photodetector, wherein the signal processing unit is configured to calculate the temperature of the active optical cavity using Bragg grating inscribed on an interior surface of the active optical cavity.

13. The heating element of claim 1, further comprising a fully-reflective attenuator configured to reflect the light beam from a second end of the active optical cavity back to a first end of the active optical cavity.

14. A heating element for vaporizing a vaporizable substance in an electronic vaporization device comprising:
an active optical cavity coupled with a vaporizable substance; and
a laser source configured to emit a light beam into the active optical cavity;
wherein the active optical cavity comprises a light transducing material configured to absorb a portion the light beam to thereby convert the optical radiation of the light beam into heat.

15. The heating element of claim 14, further comprising a photodetector configured to measure the light beam transmitted from the active optical cavity and a signal processing unit coupled with the photodetector, wherein the signal processing unit is configured to calculate the temperature of the active optical cavity based on the measurement from the photodetector.

16. A method of operating a heating element to heat a vaporizable substance, wherein the heating element comprises an active optical cavity, the method comprising the steps of:
emitting a light from a light source;
condensing the light emitted from the light source into a light beam;
transmitting the light beam into the active optical cavity; and
absorbing at least a portion of the light beam within the active optical cavity to generate heat.

17. The method of claim 16, further comprising measuring the light beam exiting the active optical cavity with a photodetector.

18. The method of claim 17, further comprising calculating the temperature of the active optical cavity based on the measurement of the photodetector based on a select one or more of the at least a portion of the light beam absorbed by the active optical cavity and the Bragg grating inscribed on an interior surface of the active optical cavity.

19. The method of claim 16, further comprising vaporizing a vaporizable substance from the heat generated by the active optical cavity to produce a vapor that is substantially free from trace metals.

20. The method of claim 19, wherein the trace metals are selected from a group consisting of nickel, aluminum, silver, chromium, iron, Kanthal, Nichrome, platinum, and combinations thereof.
